(19) United States
(12) Patent Application Publication
(10) Pub. No.: US 2015/0371961 A1
(43) Pub. Date: Dec. 24, 2015

(54) SEMICONDUCTOR DEVICE

(71) Applicant: Panasonic Corporation, Kadoma-shi, Osaka (JP)

(72) Inventors: Shigeki NAKAMURA, Kanagawa (JP); Kouji TAKAHASHI, Kanagawa (JP)

(21) Appl. No.: 14/764,745

(22) PCT Filed: Nov. 29, 2013
(86) PCT No.: PCT/JP2013/007040

§ 371 Date: Jul. 30, 2015

(30) Foreign Application Priority Data
Feb. 28, 2013 (JP) 2013-038599

(51) Int. Cl. H01L 23/66; H01L 23/522; H01L 23/532; H01L 23/58; H01L 29/06

(52) U.S. Cl. CPC H01L 23/66; H01L 23/585; H01L 29/0649; H01L 23/53271; H01L 23/5228; H01L 2223/6605

(57) ABSTRACT

A semiconductor device capable of, regardless of frequency, suppressing propagation of unnecessary signals to a semiconductor element or a semiconductor circuit through a semiconductor substrate, and of suppressing deterioration of signal quality of the semiconductor device caused by parasitic capacitive coupling. The semiconductor device is provided with a semiconductor substrate (100), a semiconductor element (105) which is provided on the surface portion of the semiconductor substrate (100) and which emits signals, a signal line (103) which is connected to the semiconductor element (105), and a polysilicon layer (102) which is provided between the semiconductor substrate (100) and the signal line (103).

### TECHNICAL FIELD

The present disclosure relates to a semiconductor apparatus provided with a semiconductor circuit and semiconductor devices making up of an analog circuit, a digital circuit or an mixed signal circuit in baseband to RF (Radio Frequency) band (high-frequency band). In particular, the present disclosure relates to a semiconductor apparatus that prevents signal interference propagating from a signal line.

### BACKGROUND ART

In recent years, demands for miniaturization and cost reduction of modules used in electric apparatuses such as radio equipment are becoming increasingly strong. To satisfy such demands, in the field of semiconductor apparatuses, reduction of the chip layout area, high-frequency band block and baseband block integrates to a single chip, and mixed-signal integration have been promoted. However, in semiconductor apparatuses with such configurations, suitable measures for isolation have to be taken since signal interference between devices, blocks, or chips is significant and problems are caused in signal processes.

An example of conventional isolation techniques is a technique using a trench-type insulation region for electrically separating semiconductor devices (see, for example, PTL 1).

FIG. 1 is a cross-sectional view illustrating a semiconductor substrate adopting a conventional isolation technique.

In FIG. 1, semiconductor substrate 300 includes first layer 303, second layer 304 provided on the surface side of semiconductor substrate 300. In addition, in second layer 304, two semiconductor devices (photodiodes) 305 respectively connected with S1 port (signal line) 301 and S2 port (signal line) 302 are provided. In addition, in semiconductor substrate 300, trench-type insulation region 306 is provided such that it surrounds semiconductor device 305 (second layer 304) connected with S1 port 301.

In the semiconductor apparatus having the configuration illustrated in FIG. 1, one trench is provided between semiconductor devices 305, and thus it is possible to prevent signal interference in the direction (in FIG. 1, lateral direction) parallel with the surface of semiconductor substrate 300. In addition, by increasing the resistivity of a substrate disposed on the lower side of semiconductor device 305, the signal that propagates to further downward of trench-type insulation region 306, that is, a position deeper than a predetermined depth and propagates in the lateral direction (that is, the signal that bypasses the trench) is attenuated. In this manner, isolation is enhanced.

### CITATION LIST

### Patent Literature

PTL 1

Japanese Patent Application Laid-Open No. 2007-67012

### SUMMARY OF INVENTION

### Technical Problem

Here, due to parasitic capacitance between the semiconductor substrate and the signal line, the semiconductor substrate and the signal line are electrically coupled to each other (parasitic capacitance coupling). By parasitic capacitance coupling, a signal propagating in a signal line connected with a certain semiconductor device propagates to the other semiconductor devices or the other semiconductor circuits through the semiconductor substrate, and consequently signal interference is caused. In contrast, in the above-mentioned conventional configuration, isolation in the semiconductor substrate is taken into consideration, and as a result the signal quality of semiconductor apparatus is degraded by signal interference due to signal propagation from the above-mentioned signal line (unnecessary signal propagation). In particular, since the influence of parasitic capacitance as the frequency increases, the influence of parasitic capacitance coupling on signal quality degradation is especially significant in semiconductor apparatuses intended for high-frequency bands.

An object of the present disclosure is to provide a semiconductor apparatus in which, irrespective of frequency, unnecessary signal propagation of to a semiconductor device or a semiconductor circuit through a semiconductor substrate can be limited, and degradation of the signal quality of the semiconductor apparatus can be limited.

### Solution to Problem

A semiconductor apparatus reflecting an aspect of the present disclosure includes: a semiconductor substrate; a semiconductor device that is provided on a surface of the semiconductor substrate, and outputs a signal; a signal line that is connected with the semiconductor device; and a polysilicon layer that is provided at a position on the semiconductor substrate and immediately below the signal line.

### Advantageous Effects of Invention

According to the present disclosure, irrespective of frequency, unnecessary signal propagation to a semiconductor device or a semiconductor circuit through a semiconductor substrate can be limited, and degradation of signal quality of a semiconductor apparatus can be limited.

### BRIEF DESCRIPTION OF DRAWINGS

FIG. 1 is a cross-sectional view illustrating a semiconductor substrate using a conventional isolation technique;

FIG. 2 is a cross-sectional view illustrating a semiconductor substrate according to an embodiment of the present disclosure;

FIG. 3 is a plan view illustrating the semiconductor substrate according to the embodiment of the present disclosure;

FIG. 4 shows frequency-isolation characteristics of the embodiment of the present disclosure;

FIG. 5 illustrates another example of the semiconductor substrate according to the embodiment of the present disclosure;

FIG. 6 illustrates another example of the semiconductor substrate according to the embodiment of the present disclosure; and

FIG. 7 illustrates another example of the semiconductor substrate according to the embodiment of the present disclosure.

### DESCRIPTION OF EMBODIMENTS

In the following, embodiments of the present disclosure will be described in detail with reference to the accompanying drawings.

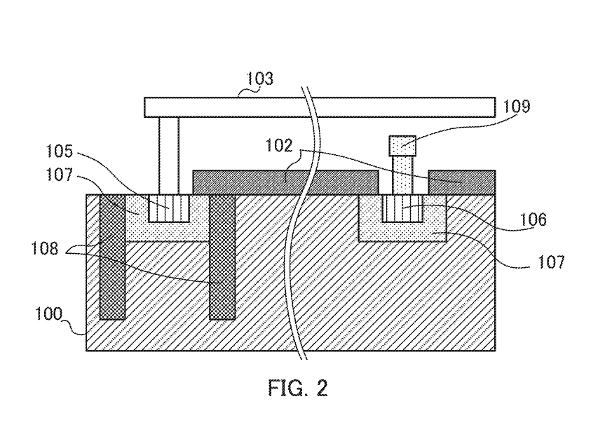

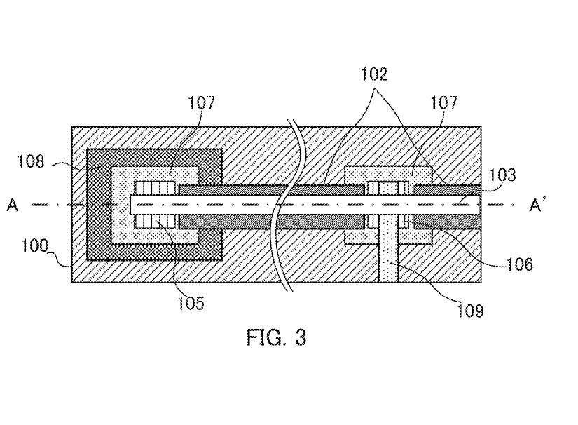

FIG. 2 is a cross-sectional view of semiconductor substrate 100 in a semiconductor apparatus according to the present embodiment, and FIG. 3 is a plan view as viewed from the surface side of semiconductor substrate 100. It is to be noted that FIG. 2 is a cross-sectional view taken along line A-A′ of FIG. 3.

First layer 107 is provided on the surface side of semiconductor substrate 100 illustrated in FIG. 2, and semiconductor device 105 and semiconductor device 106 are provided on the surface of first layer 107 (that is, on the surface of semiconductor substrate 100).

Semiconductor devices 105 and 106 output signals. Examples of semiconductor devices 105 and 106 include an integrated circuit of an analog circuit, a digital circuit and the like, an active device such as a bipolar transistor and a MOS transistor, and a passive device such as a resistor, an inductor, and a capacitor.

A signal which is output from semiconductor device 105 during operation of semiconductor device 105 propagates through signal line 103.

A signal which is output from semiconductor device 106 during operation of semiconductor device 106 propagates through signal line 109.

Signal line 103 and signal line 109 are, for example, metal interconnections which are made of a highly conductive metal material such as aluminum and copper. In addition, signal line 103 is connected with semiconductor device 105 through a via, but is not connected with semiconductor device 106. Likewise, signal line 109 is connected with semiconductor device 106 through via, but is not connected with semiconductor device 105.

Polysilicon layer 102 is provided at a position immediately below signal line 103 and above semiconductor substrate 100. It is to be noted that polysilicon layer 102 is provided on the surface of semiconductor substrate 100 through an insulating film such as a silicon oxide film. In addition, polysilicon layer 102 is not physically connected with signal line 103. For example, polysilicon layer 102 has an extremely high resistance in comparison with at least the surface of semiconductor substrate 100.

In addition, as illustrated in FIG. 3, the width of polysilicon layer 102 is greater than at least the width of signal line 103. Desirably, as illustrated in FIG. 3, in a region immediately below signal line 103 in the direction along signal line 103 (in FIG. 3, lateral direction), polysilicon layer 102 is not provided above single element devices such as a semiconductor device, and polysilicon layer 102 is provided as much as possible in the other regions where the design rules are satisfied. For example, in FIG. 3, in a region immediately below signal line 103 in the direction along signal line 103, polysilicon layer 102 is provided in a region other than a region where semiconductor device 105 and semiconductor device 106 that is not connected with signal line 103 are provided.

It is to be noted that in FIG. 2 and FIG. 3, polysilicon layer 102 which corresponds to signal line 103 is illustrated. However, in semiconductor substrate 100, a polysilicon layer which corresponds to signal line 109 may be provided in the same manner. To be more specific, semiconductor substrate 100 may include a polysilicon layer which is provided at a position on semiconductor substrate 100 and immediately below signal line 109.

In the semiconductor apparatus having the above-mentioned structure, for example, when semiconductor device 105 operates, a signal or noise caused by a signal diffuses in various directions with respect to semiconductor substrate 100, and propagates on signal line 103 connected with semiconductor device 105 through a via (not illustrated).

At this time, signal line 103 is electrically coupled with polysilicon layer 102 by parasitic capacitance coupling. Consequently, the signal propagating in signal line 103 is propagated also to polysilicon layer 102. Further, since parasitic capacitance exists between polysilicon layer 102 and semiconductor substrate 100, polysilicon layer 102 and semiconductor substrate 100 are electrically coupled to each other. That is, the signal propagating in signal line 103 is propagated also to semiconductor substrate 100 through the polysilicon layer.

However, as described above, since polysilicon layer 102 has an extremely high resistance, the signal propagated from signal line 103 to polysilicon layer 102 is considerably attenuated at polysilicon layer 102. Therefore, the signal component propagated from polysilicon layer 102 to semiconductor substrate 100 is an extremely small signal.

In this manner, by forming polysilicon layer 102 between signal line 103 and semiconductor substrate 100, isolation is enhanced. That is, signal interference that is caused when a signal propagating in signal line 103 is propagated to semiconductor substrate 100 can be limited, and degradation of the signal quality of the semiconductor apparatus can be prevented.

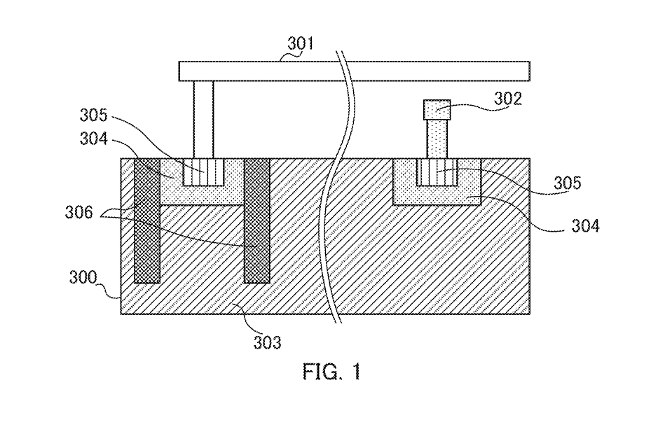

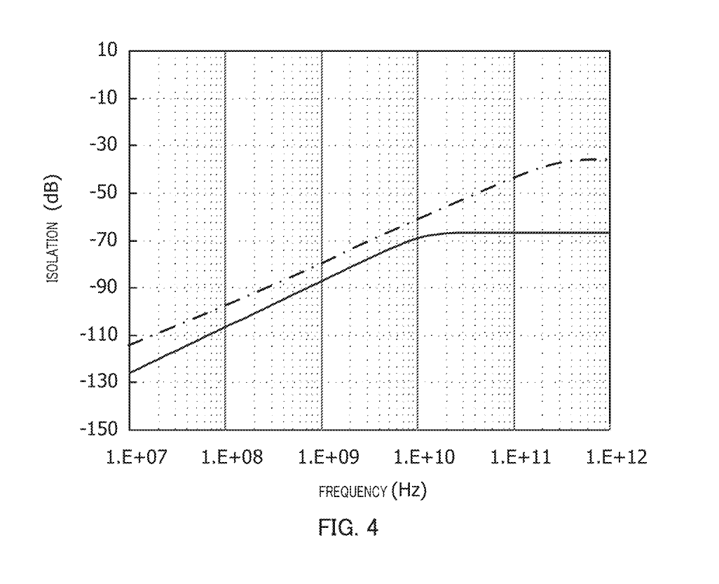

FIG. 4 illustrates frequency-isolation characteristics of the semiconductor apparatus having the configuration according to the present embodiment (FIG. 2 and FIG. 3) and a semiconductor apparatus having a conventional configuration (for example, FIG. 1).

In FIG. 4, the abscissa represents frequency [Hz], and the ordinate represents isolation [dB]. In addition, the solid line shows the characteristics of the semiconductor apparatus having the configuration according to the present embodiment (that is, the configuration including polysilicon layer 102), and the dashed line shows the characteristics of a semiconductor apparatus having a conventional configuration (that is, a configuration not including the polysilicon layer).

FIG. 4 shows that isolation is enhanced in all frequencies in the configuration of the present embodiment in comparison with the conventional configuration. In particular, in comparison with the conventional configuration, the isolation is more enhanced as the frequency is increased in the high-frequency band (approximately 1 GHz or more), and therefore it can be said that the configuration of the present embodiment can enhance isolation in comparison with the conventional configuration. That is, isolation can be enhanced also at high frequencies where parasitic capacitance coupling causes more degradation of signal quality.

As described above, according to the present embodiment, the polysilicon layer is provided at a position on the semiconductor substrate and immediately below the signal line through which a signal generated in the semiconductor device is propagated, and thus, propagation of (unnecessary signal propagation) a signal from the signal line to the semiconductor substrate due to parasitic capacitance coupling can be prevented. To be more specific, even when the signal line (metal interconnection) and the polysilicon layer are electrically coupled to each other by capacitance coupling and the signal propagating in the signal line is propagated to the polysilicon layer, the signal is attenuated since the polysilicon layer has a high resistance, and the signal propagated to semiconductor substrate can be reduced.

Thus, according to the present embodiment, regardless of the frequency, unnecessary signal propagation to a semiconductor device or a semiconductor circuit through a semiconductor substrate can be limited, and degradation in signal quality of a semiconductor apparatus can be limited.

### Other Embodiments

In the above-mentioned embodiment, polysilicon layer 102 is provided immediately below signal line 103. However, the layer provided immediately below signal line 103 is not limited to the polysilicon layer as long as the layer is composed of a material (insulation layer) which can limit unnecessary signal propagation from the signal line to the semiconductor substrate due to parasitic capacitance between the signal line and the semiconductor substrate.

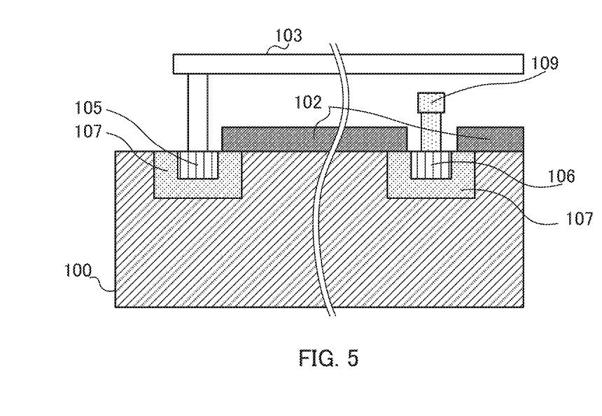

In addition, in the above-mentioned embodiment, the configuration of semiconductor substrate 100 illustrated in FIG. 2 is adopted as an example of as the configuration of the semiconductor substrate, but the configuration of the semiconductor substrate is not limited to the configuration illustrated in FIG. 2. To be more specific, as illustrated in FIG. 5, the configuration in semiconductor substrate 100 is not limited as long as the configuration includes polysilicon layer 102 provided at a position on semiconductor substrate 100 and immediately below signal line 103.

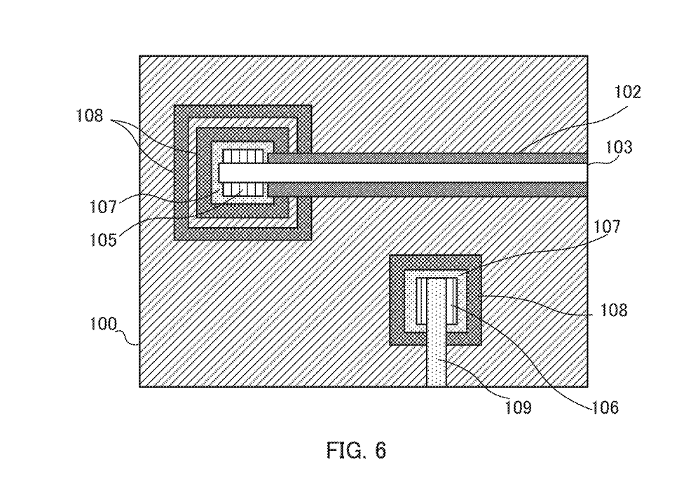

For example, in semiconductor substrate 100, trench-type insulation region 108 surrounding semiconductor device 105 is not limited to the single surrounding structure illustrated in FIG. 1, and double or more surrounding structure may also be adopted. In addition, while, in FIG. 1, semiconductor substrate 100 has a structure in which trench-type insulation region 108 surrounds semiconductor device 105, trench-type insulation region 108 may surround semiconductor device 106. FIG. 6 illustrates an exemplary configuration in which trench-type insulation region 108 is provided to surround semiconductor device 105 with a double surrounding structure, and trench-type insulation region 108 is provided to surround semiconductor device 106 with a single surrounding structure.

In addition, the configuration for enhancing isolation in semiconductor substrate 100 is not limited to the configuration in which the trench-type insulation region is provided, and it is also possible to adopt a configuration in which a guard ring is provided to surround the semiconductor device, or a configuration in which the trench-type insulation region is used with a guard ring, for example. In addition, a guard ring that surrounds the semiconductor device may have the single surrounding structure or the double or more surrounding structure.

In addition, for example, in the semiconductor substrate, a material having a resistivity, or a plurality of materials having different resistivities may be used for the semiconductor substrate.

Alternatively, the above-described exemplary configurations in semiconductor substrate 100 may be appropriately combined.

With the above-mentioned configurations in semiconductor substrate 100, not only unnecessary signal propagation from the signal line, but also unnecessary signal propagation in the semiconductor substrate can be prevented, and thus isolation can be further enhanced.

In addition, polysilicon layer 102 may be electrically connected to the materials, or may not be connected to the materials.

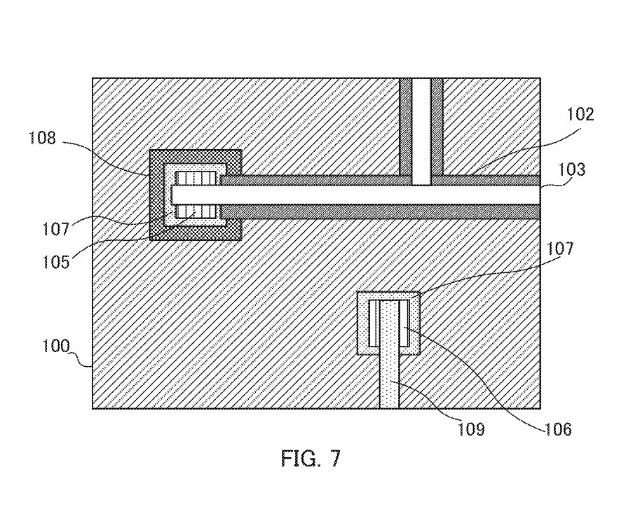

In addition, in FIG. 3, semiconductor device 106 that is not physically connected with signal line 103 is provided immediately below signal line 103. However, for example, as illustrated in FIG. 7, even in the case where semiconductor device 106 that is not physically connected with signal line 103 is not provided immediately below signal line 103, signal interference caused by parasitic capacitance coupling from signal line 103 is limited by polysilicon layer 102 as with the above-mentioned embodiment, whereby unnecessary signal propagation from signal line 103 to semiconductor device 106 through semiconductor substrate 100 is limited, and degradation in signal quality of the semiconductor apparatus can be limited.

In addition, while signal line 103 is provided in one direction in FIG. 3, signal line 103 may be diverged in multiple directions as illustrated in FIG. 7, for example. Also in this case, it suffices to form polysilicon layer 102 immediately below signal line 103.

This application is entitled to and claims the benefit of Japanese Patent Application No. 2013-038599 filed on Feb. 28, 2013, the disclosure of which including the specification, drawings and abstract is incorporated herein by reference in its entirety.

### INDUSTRIAL APPLICABILITY

The present disclosure is applicable to a semiconductor apparatus. In particular, the present disclosure is suitable for preventing signal interference and enhancing isolation in a semiconductor apparatus and the like provided with a semiconductor circuit and a semiconductor device composing an analog circuit, a digital circuit, or mixed signal circuit in baseband to RF band.

### REFERENCE SIGNS LIST

100, 300 Semiconductor substrate
102 Polysilicon layer
103, 109 Signal line
105, 106, 305 Semiconductor device
107, 303 First layer
301 S1 port
302 S2 port
304 Second layer
108, 306 Trench-type insulation region

1. A semiconductor apparatus comprising:
a semiconductor substrate;
a semiconductor device that is provided on a surface of the semiconductor substrate, and outputs a signal;
a signal line that is connected with the semiconductor device; and
a polysilicon layer that is provided between the semiconductor substrate and the signal line.

2. The semiconductor apparatus according to claim 1, wherein the polysilicon layer has a width that is greater than at least a width of the signal line.

3. The semiconductor apparatus according to claim 1, wherein the polysilicon layer is provided in a region other than a region where the semiconductor device and another semiconductor device that is not connected with the signal line are provided.

4. The semiconductor apparatus according to claim 1, wherein a trench-type insulation region is provided in the semiconductor substrate such that the trench-type insulation region surrounds at least one of the semiconductor device and another semiconductor device not connected with the signal line with at least a single surrounding structure.

5. The semiconductor apparatus according to claim 1, wherein a guard ring is provided in the semiconductor substrate such that the guard ring surrounds at least one of the semiconductor device and another semiconductor device not connected with the signal line with at least a single surrounding structure.

6. The semiconductor apparatus according to claim 1, wherein the semiconductor substrate is composed of a material of a single resistivity, or a plurality of layers having different resistivities.
